(19) United States
(12) Patent Application Publication
(10) Pub. No.: US 2013/0152999 A1
(43) Pub. Date: Jun. 20, 2013

(54) PHOTOVOLTAIC COMPONENT FOR USE UNDER CONCENTRATED SOLAR FLUX

(71) Applicants: Daniel Lincot, Antony (FR); Myriam Paire, Paris (FR); Jean-François Guillemoles, Paris (FR); Jean-Luc Pelouard, Paris (FR); Stéphane Collin, Paris (FR)

(72) Inventors: Daniel Lincot, Antony (FR); Myriam Paire, Paris (FR); Jean-François Guillemoles, Paris (FR); Jean-Luc Pelouard, Paris (FR); Stéphane Collin, Paris (FR)

(73) Assignee: CENTRE NATIONAL DE LA RECHERCHE SCIENTIFIQUE-CNRS, Paris (FR)

(21) Appl. No.: 13/701,699

(22) PCT Filed: May 31, 2011
(86) PCT No.: PCT/EP2011/058971

§ 371 Date: Feb. 14, 2013

(30) Foreign Application Priority Data
Jun. 2, 2010 (FR) 1054318

(51) Int. Cl. H01L 31/0224; H01L 31/052; H01L 31/18; H01L 31/05

(52) U.S. Cl. CPC H01L 31/022466; H01L 31/0512; H01L 31/0522; H01L 31/1884
USPC 136/246; 136/256; 136/244; 438/98

(57) ABSTRACT

A photovoltaic component including a set of layers suitable for producing a photovoltaic device is disclosed. The component has at least one first layer made of a conductive material forming a back electrical contact, a second layer made of a material that is absorbent in the solar spectrum, and a third layer made of a transparent conductive material forming a front electrical contact, and an electrically insulating layer arranged between said back electrical contact and said front electrical contact. The third layer is discontinuous in order to allow said layers of said set of layers to be stacked in one or more zones to form, in each of these zones, an active photovoltaic zone, and a fourth layer made of a conductive material, making electrical contact with said third layer made of a transparent conductive material, to form a peripheral electrical contact for each of said photovoltaic microcells.

### PRIOR ART

1. Technical field of the invention

The present invention relates to a photovoltaic component for use under a concentrated solar flux, and to its manufacturing process, and especially relates to the field of thin-film photovoltaic cells.

2. Prior art

In the field of solar cells, those based on thin films are currently the focus of intense activity, to the detriment of the crystalline silicon traditionally used. This industrial tendency is mainly due to the fact that these films, smaller than 20 μm in thickness and typically smaller than 5 μm in thickness, have an absorption coefficient for solar light several orders of magnitude higher than that of crystalline silicon, and to the fact that they are produced directly from gas and liquid phases and thus do not need to be sawn. Thus, a thin-film photovoltaic module may be produced with a film 100 times thinner than a crystalline photovoltaic cell. As a result, the expected costs are much lower, the availability of raw materials is increased, and the process for manufacturing the modules is simpler. The main technologies being developed at the present time are polycrystalline chalcogenide technologies, and especially CdTe technology and what is called chalcopyrite technology based on the compound CuInSe₂ or its variants Cu(In, Ga)(S, Se)₂, also called CIGS, and amorphous and microcrystalline silicon technologies.

Thin-film solar cells, especially those based on chalcopyrite materials such as Cu(In, Ga)Se₂ or CdTe, have, at the present time, achieved laboratory efficiencies of 20% and 16.5%, respectively, under one sun illumination (i.e. 1000 W/m²). However, the materials used to manufacture solar cells are sometimes limited in their availability (indium or tellurium, for example). In the context of the development of photovoltaic power stations with capacities of the order of several GW, problems with the availability of raw materials will possibly become a major constraint.

Recently, concentrated photovoltaics (CPV) technology has been undergoing development; this technology uses photovoltaic cells under a concentrated solar flux. Concentration of light allows the conversion efficiency of the cell to be increased and therefore raw material can be saved by a factor greater than the light concentration employed, for a given electricity production. This is of particular importance in thin-film technologies. Trials under concentration have demonstrated that efficiencies of 21.5% can be obtained under low concentration (14 suns, i.e. 14 times the average luminous power received by the Earth from the sun) if the frontside collecting grid has been optimized (see, for example, J. Ward et al. “Cu(In,Ga)Se₂ Thin film concentrator Solar Cells”, Progress in Photovoltaics 10, 41-46, 2002). Above this concentration, dissipative effects due to the resistance of the collecting layer become too great for efficiency to be improved whatever the design of the frontside collecting grid, which, moreover, shades the cell (as much as 16% being shaded). Concentrator photovoltaics, though experiencing rapid growth at the present time, thus remain limited to simple III-V semiconductor junction or multijunction cells, which are very costly.

One object of the invention is to produce a photovoltaic cell that works under a very high concentration with a substantial reduction in the adverse effects of the resistance of the frontside layer. To do this, an innovative architecture has been developed, especially allowing arrays of microcells with contacts on their periphery to be produced, thereby making it possible to dispense with the use of a collecting grid. This architecture is compatible with existing solar cell technologies, especially thin-film technologies, and could enable a considerable saving in the use of rare chemical elements (indium, tellurium, gallium).

### SUMMARY OF THE INVENTION

According to a first aspect, the invention relates to a photovoltaic component comprising:
a set of layers suitable for producing a photovoltaic device, including at least one first layer made of a conductive material forming a back electrical contact, a second layer made of a material that is absorbent in the solar spectrum, and a third layer made of a transparent conductive material forming a front electrical contact;
an electrically insulating layer, arranged between said back electrical contact and said front electrical contact, containing a plurality of apertures, each aperture defining a zone in which said layers of said set of layers are stacked to form a photovoltaic microcell; and
a layer made of a conductive material, making electrical contact with said third layer made of a transparent conductive material, forming the front electrical contact with said third layer, and structured in such a way as to form a peripheral electrical contact for each of said photovoltaic microcells formed, said microcells being electrically connected in parallel by the back electrical contact and the front electrical contact.

For example, said conductive material forming the layer made of a conductive material making electrical contact with said third layer made of a transparent conductive material is a metal chosen from aluminum, molybdenum, copper, nickel, gold, silver, carbon and carbon derivatives, platinum, tantalum and titanium.

According to one embodiment, the first layer made of a conductive material of the back contact is transparent, and the back contact further comprises a layer made of a conductive material making electrical contact with said layer made of a transparent conductive material structured in such a way as to form a peripheral electrical contact for said photovoltaic microcells.

According to another embodiment, the insulating layer comprises a layer made of an insulating material structured in such a way as to form a plurality of apertures.

According to another embodiment, the photovoltaic component according to the first aspect further comprises a second layer made of an insulating material, said layer being arranged between said back electrical contact and said front electrical contact, and being structured in such a way as to form a plurality of apertures centered on said apertures in the first layer made of insulating material, and of equal or smaller size.

For example, said insulating material is chosen from oxides such as silica or alumina, nitrides such as silicon nitride, and sulfides such as zinc sulfide.

Alternatively, the insulating layer comprises an insulating gas, for example air.

According to one preferred embodiment of the invention, at least one dimension of the section of the photovoltaic microcells is smaller than 1 mm and preferably smaller than 100 μm.

According to another embodiment, at least some of the photovoltaic microcells have a circular section with an area smaller than 10⁻² cm² and preferably smaller than 10⁻⁴ cm².

According to another embodiment, the photovoltaic component according to the first aspect comprises at least one photovoltaic microcell with a strip-shaped elongate section, the smaller dimension of which is smaller than 1 mm and preferably smaller than 100 μm.

According to another embodiment, the layer made of an absorbent material is discontinuous and formed in the location of the photovoltaic microcells.

According to another preferred embodiment of the invention, the photovoltaic component is a thin-layer component, each of the layers forming the cell having a thickness of less than about 20 μm and preferably of less than 5 μm.

For example, the absorbent material belongs to a family chosen from the CIGS family, the CdTe family, the silicon family, and the III-V semiconductor family.

According to a second aspect, the invention relates to an array of photovoltaic components according to the first aspect, in which said photovoltaic components are electrically connected in series, the front contact of one photovoltaic component being electrically connected to the back contact of the adjacent photovoltaic component.

According to a third aspect, the invention relates to a photovoltaic module comprising one or an array of photovoltaic components according to the first or second aspect, and further comprising a system for concentrating solar light, this system being suitable for focusing all or some of the incident light on each of said photovoltaic microcells.

According to one embodiment, the photovoltaic module according to the third aspect further comprises an element for converting the wavelength of the incident light to a spectral band absorbed by the absorbent material arranged under said first layer made of a transparent conductive material of the back contact, the back electrical contact comprising a layer made of a transparent conductive material and a layer made of a conductive material, and the latter layer being structured in such a way as to form a peripheral electrical contact for said photovoltaic microcells.

According to a fourth aspect, the invention relates to a method for manufacturing a photovoltaic component according to the first aspect, which method comprises depositing said layers forming the component on a substrate.

According to one embodiment, the manufacturing method comprises:
depositing said first layer made of a conductive material on a substrate so as to form the back electrical contact;
depositing a layer made of a material that is inactive with respect to the photovoltaic device, preferably an electrical insulator, said inactive layer being structured to form a plurality of apertures;
selectively depositing the absorbent material in said apertures so as to form said second layer made of an absorbent material, said layer being discontinuous;
depositing said layer made of a conductive material, said layer being structured in such a way as to form apertures of smaller or equal sizes to those of the apertures in said inactive layer; and
depositing said third layer made of a transparent conductive material making electrical contact with said layer made of a conductive material, the latter layer being structured so as to form the front electrical contact.

According to another embodiment, the manufacturing method comprises:
depositing said first layer made of a conductive material on a substrate so as to form the back electrical contact;
depositing said second layer made of an absorbent material, said layer being discontinuous and containing a plurality of apertures;
selectively depositing in said apertures a material that is inactive with respect to the photovoltaic device, preferably an electrical insulator, so as to form a discontinuous inactive layer having apertures in the location of the absorbent material;
depositing said layer made of a conductive material, this layer being structured in such a way as to form apertures of smaller or equal sizes to those of the apertures in said inactive layer; and
depositing said third layer made of a transparent conductive material, this layer making electrical contact with said layer made of a conductive material, the latter layer being structured to form the front electrical contact.

According to another embodiment, the manufacturing method comprises:
depositing, on a substrate, said first layer made of a conductive material so as to form the back electrical contact, and said second layer made of an absorbent material;
depositing a layer of resist structured to form one or more pads the shape of which will define the shape of each of the photovoltaic microcells;
depositing on said resist layer a layer made of an insulating material and a layer made of a conductive material; and
lifting off the resist in order to obtain said structured layer made of an insulating material and said structured layer made of a conductive material, and depositing said third layer made of a transparent conductive material, this layer making electrical contact with said structured layer made of a conductive material, so as to form the front electrical contact.

According to another embodiment, the manufacturing method comprises:
depositing said third layer made of a transparent conductive material on a transparent substrate so as to form the front electrical contact;
depositing a layer of resist structured to form a plurality of pads the shape of which will define the shape of each of said photovoltaic microcells;
depositing on said resist layer a layer made of a conductive material and a layer made of an insulating material;
lifting off the resist in order to obtain said structured layer made of an insulating material and said structured layer made of a conductive material, and depositing the layer made of an absorbent material; and
depositing said first layer made of a conductive material so as to form the back electrical contact.

Advantageously, said layer made of an absorbent material is formed selectively, and forms a discontinuous layer.

### BRIEF DESCRIPTION OF THE DRAWINGS

Other advantages and features of the invention will become apparent on reading the description, which is illustrated by the following figures:

FIGS. 1A to 1C are diagrams showing the principle of microcells according to the invention in various embodiments;

FIG. 2 is a diagram illustrating the series connection of two islands each comprising an array of microcells according to the invention;

FIGS. 3A to 3D are diagrams illustrating set of layers for forming cells according to the invention in various embodiments;

FIGS. 4A to 4D are diagrams illustrating embodiments of cells according to the invention in the case of a CIGS, CdTe, amorphous silicon and crystalline silicon junction, respectively;

FIGS. 5A to 5F are diagrams illustrating, according to one embodiment, the method for manufacturing an island of microcells according to the invention, in the case of a CIGS-type junction;

FIG. 6 is a curve illustrating the efficiency evaluated for a solar cell according to one embodiment of the invention, as a function of the incident power;

FIG. 7 is a curve illustrating the efficiency evaluated for the solar cell according to the embodiment shown in FIG. 6, as a function of the area of the active zone of the cell; and

FIGS. 8A and 8B are micrographs of a microcell produced according to an embodiment of the process according to the invention.

### DETAILED DESCRIPTION

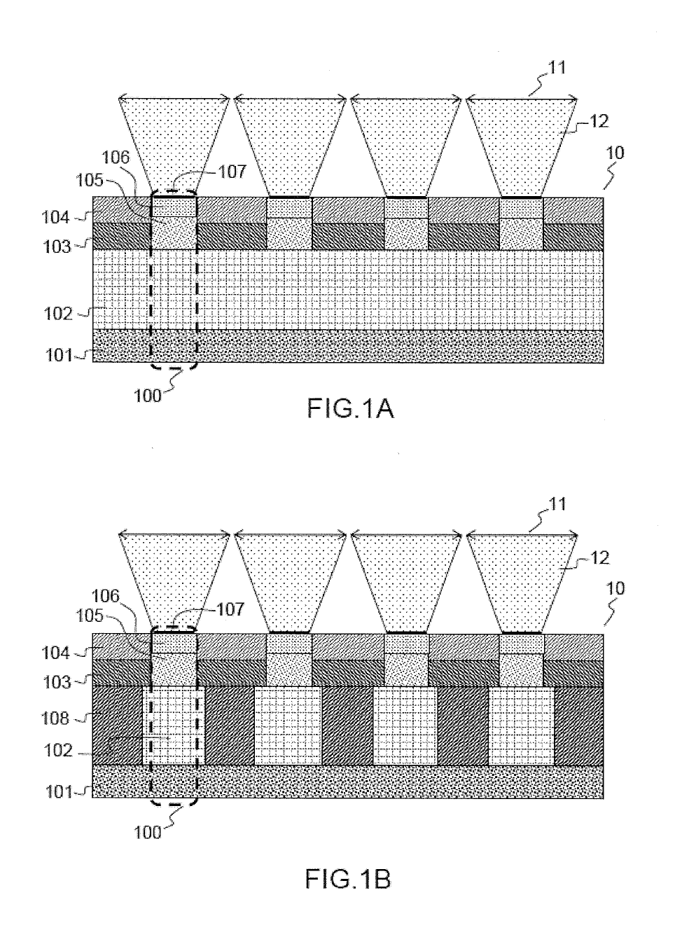

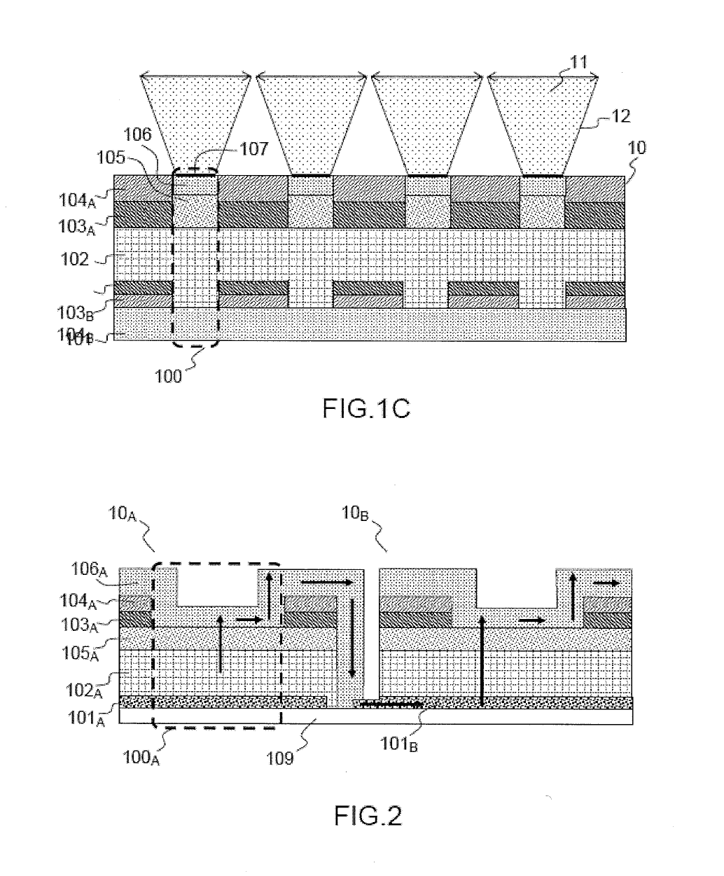

FIGS. 1A to 1C are diagrams showing the principle of photovoltaic modules with photovoltaic cells according to various embodiments of the present invention. These diagrams are by given way of illustration and the dimensions shown do not correspond to the actual scale of the cells.

These embodiments show a photovoltaic component 10 forming an island or an array of photovoltaic microcells or active photovoltaic zones 100 having an area 107 to be exposed to incident solar light and of given size and shape such that at least one dimension of the exposed area is smaller than a few hundred microns and advantageously smaller than about 100 μm. The microcells are associated with a system for concentrating solar light (symbolized in the figures by the microlenses 11) concentrating all or some of the solar light incident on each of the areas 107 of the microcells 100 (light flux indicated by the reference 12).

Each microcell comprises a set of layers suitable for producing a photovoltaic device, especially with a layer 102 made of a material that is absorbent in the visible spectrum or near-infrared (solar spectral range), or in part of the solar spectrum; a layer 101 of a conductive material forming a back electrical contact; and a layer 106 of a transparent conductive material, covering the exposed area 107, forming a front electrical contact, the layer 106 also being called a window layer. Depending on the nature of the photovoltaic device that it is desired to produce, one or more additional layers 105 may be provided, for example layers made of semiconductors or interface layers that, with the layer 102 made of an absorbent material, will contribute to form a junction. In FIGS. 1A, 1B, and 1C the front electric contact is formed by the layers 104, 106, as will be described in more detail below. In the embodiments in FIGS. 1A to 1C, the microcells 100 are connected in parallel both by the front electrical contact (106 and/or 104) and the back electrical contact 101, the front and back contacts being common to all the microcells.

According to one embodiment, the system for concentrating light allows light having a spectrum suited to the absorption range of the absorbent material of said microcell to be focused on each microcell.

The island 10 comprises an electrically insulating layer 103 arranged between the back electrical contact and the front electrical contact. The insulating layer 103 is discontinuous so as to foiin one or more apertures that define the shape and the dimensions of the microcells or active photovoltaic zones 100 of the island 10. Beyond these apertures, dark current densities are actually negligible. In the apertures, the junction is formed by the set of semiconductor layers. The front and back electrical contacts allow photogenerated charge carriers to be collected. Thus, by choosing the dimensions of the microcells (the sections of which are defined by the apertures formed in the insulating layer) such that at least one dimension of a section of the microcell is smaller than a few hundred microns, the Applicants have demonstrated that charge carriers photogenerated in each microcell can be collected by virtue of the front electrical contact while losses due to the resistance of the transparent conductive layer contributing to this contact are limited. The array thus formed forms a solar cell suited to an application under concentrated solar flux, which does not require the use of a collecting grid. The Applicants have demonstrated that, by virtue of this novel structure, theoretical efficiencies of 30% could be achieved under concentrations of more than 40,000 suns for cells in which the efficiency is 20% without concentration, considerably exceeding the concentration limits proposed until now in prior-art embodiments.

In FIGS. 1A to 1C, the microcells 100 for example have a round section, advantageously with an area smaller than 10⁻² cm², even smaller than 10⁻⁴ cm², and down to as low as 10⁻⁸ cm² or less, so as to enable rapid collection of charge carriers. The lower limit of the area is linked to technological considerations and to the mobility and lifetime properties of the carriers photogenerated in the layer of absorbent material.

The insulator may be a layer formed from an electrically insulating material pierced with apertures, such as an oxide such as silica (SiO₂) or alumina (Al₂O₃), a nitride, for example silicon nitride (Si₃N₄), a sulfide, for example zinc sulfide (ZnS), or any other insulating material compatible with the process for manufacturing the cell, for example a polymer. The insulator may also be a layer of gas, for example of air, for example contained in a porous or cellular material, or taking the form of a foam, depending on the process technology used to manufacture the component. The layer of gas, for example air, is then interrupted in zones where layers, including the layer formed by the porous material, are stacked to form the active photovoltaic zones. For example, it may be envisioned, in a silicon-based photovoltaic cell, to use a layer made of recrystallized porous silicon, in which the air bubbles formed during the anneal form the discontinuous insulating layer, the silicon forming the active photoconductive layer.

The section defines the area 107 of the active photovoltaic zones exposed to incident light and the system 11 for concentrating light will have to be modified to focus incident light onto the exposed areas of the microcells. For example, in the case of microcells with a circular section, a system comprising a network of microlenses will possibly be used, or any other known system for focusing light. The system for concentrating light is tailored to the dimensions of the illumination areas, and will itself have a smaller volume than that of a concentrating system used with a conventional cell. This has the additional advantage that less material is used to produce the system for concentrating light.

The section of the microcells may take various shapes. For example, it is possible to envision a section of elongate shape, for example a strip, with a very small transverse dimension, typically smaller than one millimeter and advantageously smaller than one hundred microns and even as small as a few microns or less. The charge carriers photogenerated at the junction may then be collected via the front contact along the smaller dimension of the strip, once more allowing the resistance effects of the window layer formed by the layer made of a transparent conductive material of the front contact to be limited. In this case, the system for concentrating light will be modified in order to focus one or more lines, following the structure of the island, on one or more strips. If the island comprises a plurality of strips, these strips will possibly be electrically connected in parallel both by the back contact and the front contact. Other shapes can be envisioned, such as for example an elongate serpentine shape, etc., providing that one of the dimensions of the section is kept small, typically smaller than a few hundred microns, for collection of charge carriers. In particular, the dimensions will possibly be optimized depending on the materials used, especially to minimize the influence of lateral electrical recombination.

Charge carriers generated in the layer 102 in the active zone bounded by the exposed area 107 are collected via the layer 106 made of a transparent conductive material or window layer, firstly in the direction perpendicular to the plane of the layers, then towards the periphery of the microcell. This layer must be sufficiently transparent to allow as much solar light as possible to penetrate into the active photovoltaic zone 100. It therefore has a certain resistivity, possibly leading to losses, but the effect of this will be limited by the size of the microcell.

The Applicants have demonstrated that peripheral charge-carrier collection is greatly improved by associating, with the window layer, a layer 104 made of a conductive material, making electrical contact with the window layer 106, the assembly of the two layers then forming the front contact. The layer 104 made of a conductive material is for example made of metal, for example of gold, silver, aluminum, molybdenum, copper, or nickel, depending on the nature of the layers to be stacked, or made of a doped semiconductor, for example ZnO:Al, sufficiently doped with aluminum to obtain the desired conductivity. Like the insulating layer 103, the layer 104 made of a conductive material is discontinuous, pierced with apertures that may be substantially superposed on those of the insulating layer so as not to interfere with the photovoltaic function of the microcell 100. The charge carriers photogenerated in the active layer 102 in the active zone are collected in the direction perpendicular to the plane of the layers by virtue of the window layer 106, then collection toward the periphery of the microcell is enabled by the conductive layer 104 which thus forms a peripheral contact of the microcell.

The layer 104 forming the peripheral contact of the microcells may completely cover the area between the microcells, or may be structured in such a way as to have peripheral contact zones with each of the microcells and electrical connection zones between said, non-overlapping, peripheral contact zones.

Since the active photovoltaic zones of the cell 10 are set by the dimensions of the one or more apertures in the insulating layer, so as to form microcells, it is possible to limit the amount of material in the layers forming the photovoltaic device, and especially the amount of absorbing material. Thus, in the embodiment in FIG. 1B, the absorbent layer 102 is discontinuous and limited to zones located in the active zones 107. The rest of the structure may be filled with a layer 108 that is inactive from the point of view of the junction, this layer possibly being an insulator, made of the same material as the layer 103. Advantageously, the zone comprising the absorbent material is slightly larger than the active photovoltaic zone defined by the aperture in the insulating layer 103 (typically a few microns), thus making it possible to marginalize the influence, on the photovoltaic microcell, of surface defects possibly related to the material itself or to the manufacturing process.

FIG. 1C shows an embodiment in which the layer 101 made of a conductive material is transparent and the back contact is formed, as the front contact (104_{A}, 106), from the layer 101 and a layer 104_{B} made of a conductive material, for example a metal, the layer 104_{B} being structured, like the layer 104_{A}, in such a way as to form a peripheral electrical contact for the active photovoltaic zones. This variant has the advantage of providing a back contact with a transparent window layer, thus forming bifacial cells, this being made possible by the peripheral collection of charge carriers and the limitation of losses due to the resistance of the transparent window layer even under concentration. This enables various applications, such as for example the production of multijunctions in which two or more photovoltaic cells are superposed on one another. Or, according to another embodiment, it allows the photovoltaic cell to be associated with a device for converting light, arranged under the window layer of the back contact, this device reflecting light that is not absorbed during a first passage through the cell (for example light in the near infrared) back toward the cell, this light having its wavelength modified (for example shifted toward the visible range, or more generally into the spectral range more readily absorbed by the absorbent material, using an “up conversion” material).

FIG. 1C shows another embodiment in which a second layer 103_{E} made of an insulating material is provided, structured substantially identically to the first layer 103_{A} made of an insulating material, with one or more apertures centered on the one or more apertures of the layer 103_{A} made of an insulating material, and of equal or smaller size. This second layer may for example have the effect of concentrating lines of current into an active photovoltaic volume.

According to one embodiment shown in FIG. 2, a plurality of islands (10_{A}, 10_{B}) may be electrically connected to form a larger photovoltaic cell. The islands are for example formed on a common substrate 109. In FIG. 2, a single microcell 100 is shown per island, but, of course, each island may comprise a plurality of microcells. In this embodiment, as in that in FIGS. 1A and 1B, the front electrical contact comprises a layer (104_{A}, 104_{B}) made of a conductive material and a window layer (106_{A}, 106_{B}) that covers, in this embodiment, all of the island. In this embodiment, the islands are connected in series by means, for example, of the window layer 106_{A} of the first island 10_{A}, which makes electrical contact with the back electrical contact 101_{E} of the second island 10_{B}. It will be understood that FIG. 2 is a diagram showing an operating principle. It may be necessary, in the case where the conductivity of the layer 102_{A} is high, to insulate the layer 106_{A}, for example by extending the insulating layer 103_{A} to level with where the islands are connected.

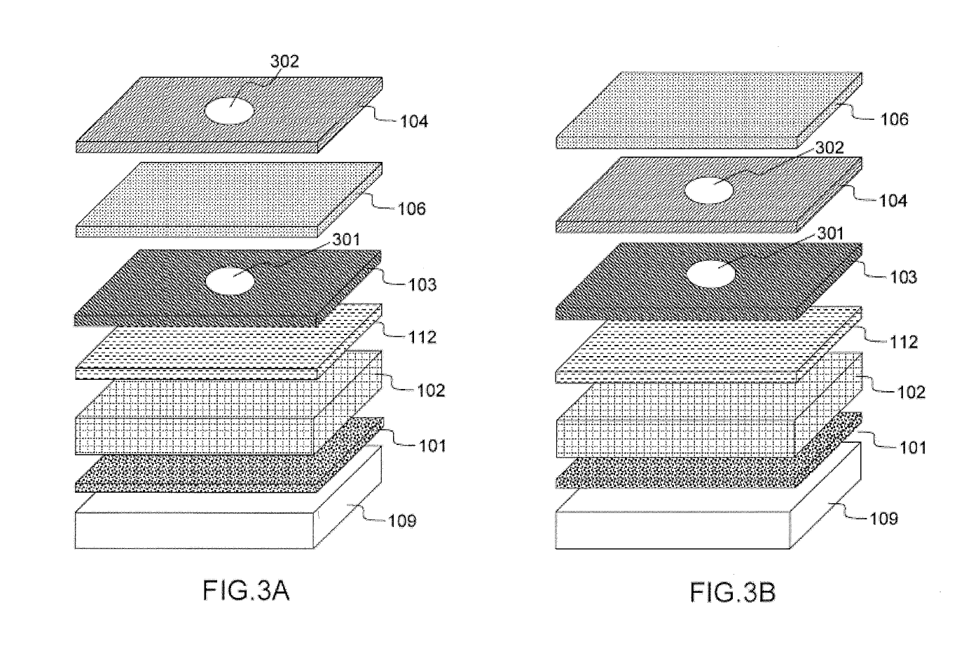

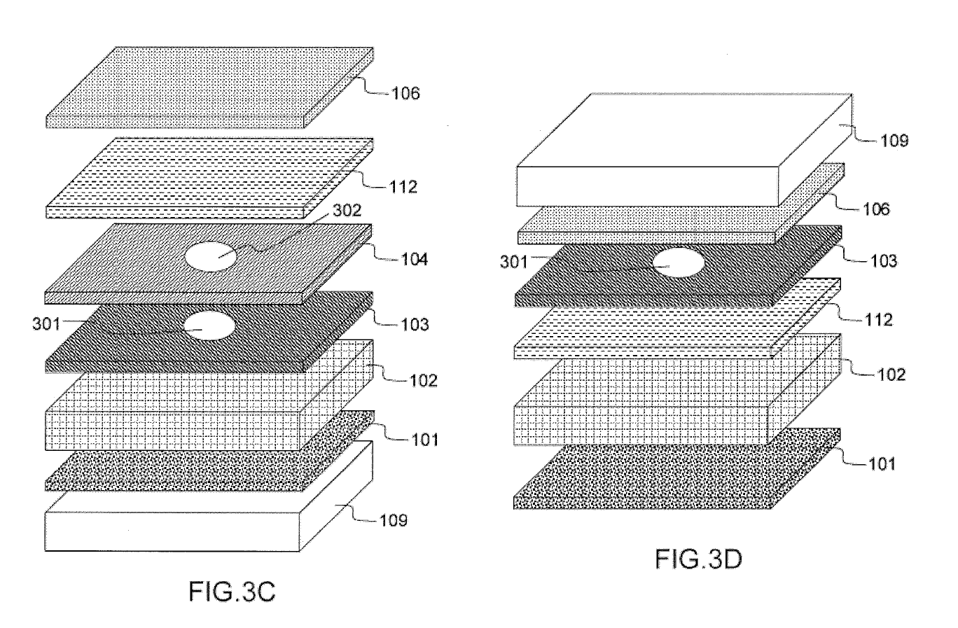

FIGS. 3A to 3D show diagrams illustrating the succession of layers used to form cells according to the invention in various embodiments. Several architectures for producing thin-layer microcells are presented here. In this technology, the photovoltaic device comprises a junction formed by means of n- and p-doped semiconductor layers, the electrically insulating layer 103 being interposed between said layers. In these embodiments, the layers forming the junction are the layers 102 (layer made of an absorbent material), 112 (representing one or more interface layers) and 106 (which founs the transparent window layer). Structuring the insulating layer makes it possible to create disks 301 of controlled area in which this layer is not deposited. The insulating layer allows circular photovoltaic cells to be defined since the p-n or n-p semiconductor junction will only be formed in the disks. The electrically conductive layer 104, for example made of a metal, structured in a similar way to the insulating layer (comprising circular holes 302), is arranged to make electrical contact with the window layer 106 in order to form, with the window layer, the frontside contact (except in the embodiment in FIG. 3D where the layer 106 alone foam the front contact). Either the conductive layer 104 is deposited on the insulating layer 103 (FIG. 3B), before the window layer 106 has been deposited, or it is deposited on the window layer (FIG. 3A). The interface layers 112 may be deposited before the insulating layer (FIGS. 3A, 3B) or after the latter (FIG. 3C), the electrical contact between the metallic layer and the window layer being preserved if the interface layer is sufficiently thin. The presence of interface layers having a very low lateral conductivity (intrinsic CdS and ZnO in the case of a CIGS cell, for example) makes it possible to ensure that the junction from the optical point of view, and the junction from the electrical point of view, are similar Thus, the electrically active parts are correctly excited by incident light, while losses due to recombination of charge carriers and the dark current of the junction are minimized

It is also possible to tailor this geometry to the case of superstrate cells (FIG. 3D) produced on a glass substrate 109 with what is called a “top to bottom” process, such as will be described below, and then flipped to allow incident light to enter via the side corresponding to the substrate.

As has been described above, the conductive layer 104, for example made of metal, makes it possible to produce an annular contact on the periphery of the microcell and common to all the microcells, this contact possibly being used directly as the front electrical contact of the cell, thereby minimizing contact resistances while avoiding shading the cell since no collecting grid is required. Interposing the layer 103 made of an insulating material structured with one or more apertures in the set of layers forming the photovoltaic device is an advantageous way in which to define the microcells, because this solution does not require mechanical etching of the set of layers, which is inevitably a source of defects.

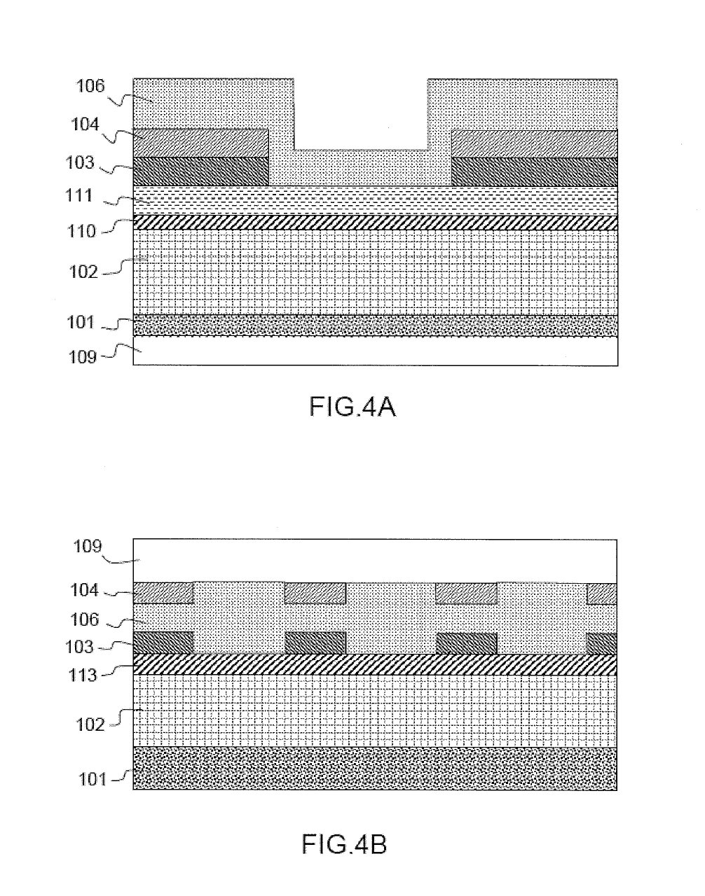

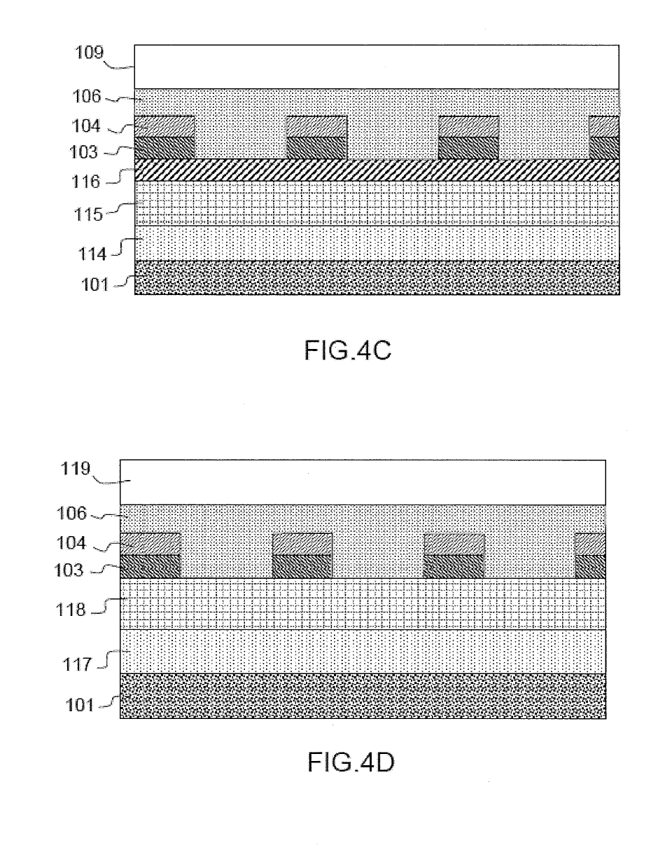

FIGS. 4A to 4D show four embodiments of cells according to the invention using CIGS, CdTe and silicon technologies, respectively. In each of these embodiments, the entire photovoltaic cell has not been shown, but only the set of layers in a microcell. Here again, these are illustrative diagrams in which the dimensions do not correspond to the actual scale of the cells.

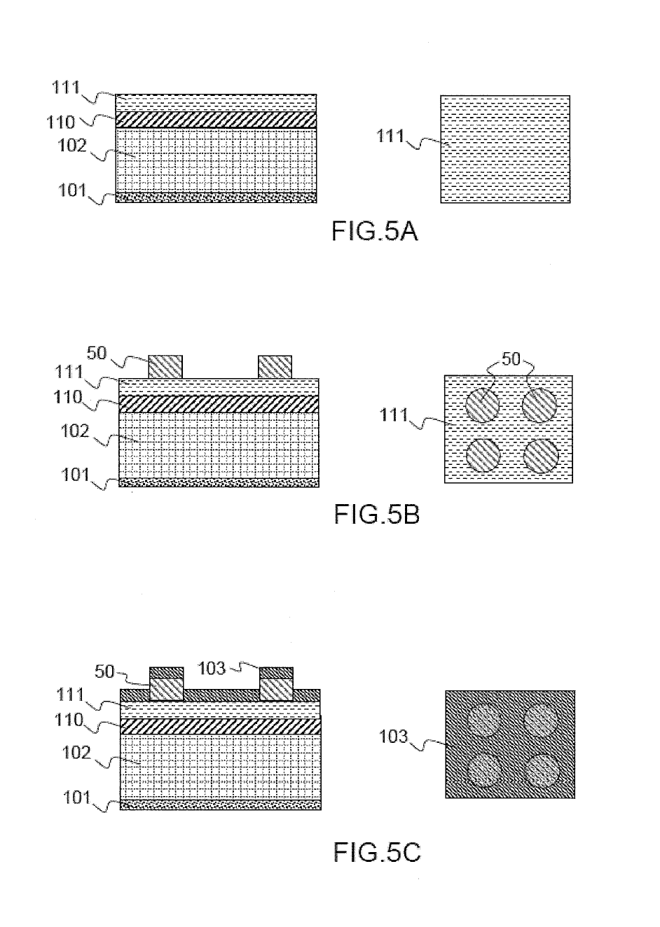

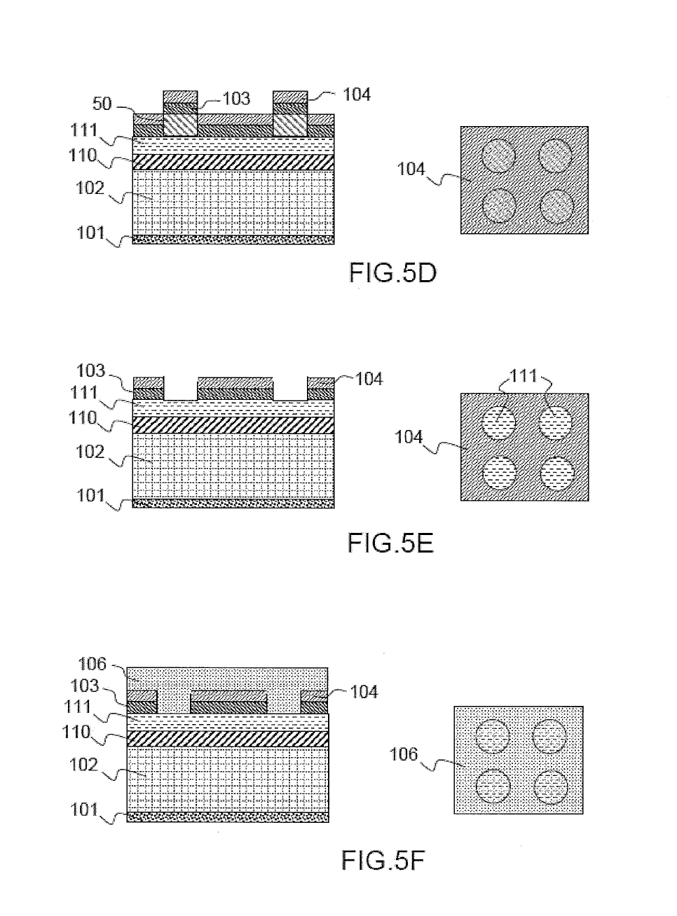

FIG. 4A shows a set of layers suitable for forming photovoltaic microcells using a CIGS-type heterojunction. The term “CIGS” is here understood in its most general sense to mean the family of materials including CuInSe₂ or one of its alloys or derivatives, in which copper may be partially substituted by silver, indium may be partially substituted by aluminum or gallium, and selenium may be partially substituted by sulfur or tellurium. The natures of the materials are given above by way of example, and may be substituted by any other material known to a person skilled in the art to obtain a functional photovoltaic device. In the embodiment illustrated in FIG. 4A, the set of layers comprises a substrate 109, for example made of glass, the thickness of the substrate typically being a few millimeters; and a layer 101 made of a conductive material, for example of molybdenum, forming the back contact. The thickness of this layer is about one micron. The layer 102 is the layer made of an absorbent semiconductor material, in this embodiment Cu(In, Ga)Se₂ (copper indium gallium diselenide). It is for example 2 or 3 μm in thickness. The layers 110 and 111 are interface layers, respectively made of n-doped CdS (cadmium sulfide) and iZnO (intrinsic zinc oxide) a few tens of nanometers, for example 50 nm, in thickness. Generally, the interface layers allow electrical defects present when the layer of absorbent material (here CIGS) and the layer made of a transparent conductive material make direct contact to be passivated, these defects possibly severely limiting the efficiency of the cells. Other materials may be used to form an interface layer, such as zinc-sulfide derivatives (Zn, Mg)(O, S) or indium sulfide In₂S₃, for example. The set of layers comprises the layer 103 made of an electrical insulating material, for example of SiO₂ (silica), structured so as to form the apertures allowing the active photovoltaic zone(s) to be defined. It is a few hundred nanometers, for example 400 nm, in thickness. The layer 104 is a layer made of a conductive material, for example a metallic layer, ensuring the peripheral contact of the microcell. It is structured identically to the insulating layer 103. It is a few hundred nanometers, for example 300 nm, in thickness. It is for example made of gold, copper, aluminum, platinum or nickel. It could also be made of highly aluminum-doped ZnO:Al. Finally, the layer 106, for example made of n-doped ZnO:Al (aluminum-doped zinc oxide), forms the front window layer and also contributes to the junction. It is also a few hundred nanometers, for example 400 nm, in thickness. An embodiment of a process for producing the structure 4A will be described in greater detail by way of FIGS. 5A to 5I.

FIG. 4B shows a set of layers suitable for forming photovoltaic microcells using a CdTe-type heterojunction. The term “CdTe” is here understood in its most general sense to mean the family of materials including CdTe or one of its alloys or derivatives, in which cadmium may be partially substituted by zinc or mercury and tellurium may be partially substituted by selenium. Here again, the natures of the materials are given above by way of example. The set of layers comprises a layer 101 made of a conductive material, for example of gold or of a nickel/silver alloy, forming the back contact. This layer is about one micron in thickness. The layer 102 is the layer made of an absorbent material, in this embodiment p-doped CdTe (cadmium telluride). It is a few microns, for example 6 μm, in thickness. An interface layer 113 made of n-doped CdS is arranged between the CdTe layer and the insulating layer 103. It is about one hundred nanometers in thickness. The set of layers comprises the layer 103 made of an electrically insulating material, for example of SiO₂, structured to form apertures allowing the one or more active photovoltaic zone(s) to be defined. It is a few hundred nanometers, for example 400 nm, in thickness. Next comes the window layer 106 made of a transparent conductive material, for example of ITO (indium tin oxide) or of n-doped SnO₂ (tin dioxide), which is a few hundred nanometers, for example 400 nm, in thickness, and the layer 104 made of a metallic material ensuring the peripheral contact of the microcell, for example made of gold, and structured identically to the insulating layer 103, and of a few hundred nanometers, for example 400 nm, in thickness. In this embodiment, the manufacturing process is a “top to bottom” process, and the substrate 109 is placed on the side of the cell intended to receive incident solar light.

FIG. 4C shows a set of layers suitable for forming photovoltaic microcells using the family of silicon thin layers comprising amorphous silicon, and/or polymorphous, microcrystalline, crystalline and nanocrystalline silicon. In the embodiment in FIG. 4C, a junction is formed by the layers 114, 115, and 116, respectively made of p-doped amorphous silicon, intrinsic amorphous silicon and n-doped amorphous silicon, these layers together being absorbent in the visible, the total thickness of the three layers being about 2 μm. The layers forming the junction are arranged between the back electrical contact 101 (metallic layer, for example made of aluminum or silver) and the structured insulating layer 103, for example made of SiO₂ and about a few hundred nanometers, for example 400 nm, in thickness. A front metallic layer 104, structured similarly to the insulating layer and of substantially the same thickness, is arranged on the latter, and on this front metallic layer 104 the window layer 106 made of a transparent conductive material, for example SnO₂, is found, the latter layer also being a few hundred nanometers in thickness. Again, in this embodiment the top to bottom process is used, the substrate being positioned on the side of the cell exposed to incident light.

Other families of absorbent materials may be used to produce a thin-layer photovoltaic cell according to the present invention. For example, III-V semiconductors such as GaAs (gallium arsenide), InP (indium phosphide) and GaSb (gallium antimonide) may be used. In any case, the nature of the layers used to form the photovoltaic device will be tailored to the device.

The last embodiment (FIG. 4D) illustrates implementation of the invention using crystalline silicon. Although the invention is particularly advantageous for thin-layer technologies, it is nevertheless also applicable to traditional crystalline-silicon technology. In this case, the layers 117 and 118, respectively made of p- (boron) doped crystalline silicon and n- (phosphorus) doped crystalline silicon, form a junction arranged between the back metal contact 101 and the insulating layer 103. In total, the junction is a few hundred microns, typically 250 um, in thickness, which makes this embodiment less attractive than a thin-layer embodiment and limits the possible reduction in the size of the microcell (typically, the minimum size here will be about 500 μm, in order to limit the influence of lateral recombination). As in the preceding embodiment, the junction is covered with the structured insulating layer 103, with the layer 104 made of a conductive material structured in the same way, and with the window layer 106, which is for example made of SnO₂. The layers 103, 104, 106 are a few hundred nanometers, for example 400 nm, in thickness. A substrate is not required because of the thickness of the layers forming the junction. An antireflection layer 119 may be provided in this embodiment, and also, more generally, in all the embodiments.

FIGS. 5A to 5F illustrate, according to one embodiment, the steps of a process for manufacturing a photovoltaic cell with a CIGS junction of the type shown in FIG. 4A.

In a first step (FIG. 5A), the basic structure is produced by depositing, in succession, on a substrate (not shown) the layer 101 made of a conductive material (for example molybdenum), the CIGS layer 102, and two interface layers 110, 111 made of CdS and iZnO, respectively. A partial top view of the basic structure is also shown. In a second step (FIG. 5B) a resist layer, for example consisting of circular pads 50 of a diameter tailored to the size of the microcell that it is desired to produce, is deposited. The resist pads are produced, for example, using a known lithography process, consisting in coating the sample with a resist layer, exposing the resist through a mask, and then soaking the sample in a developer which selectively dissolves the resist. If the photoresist used is a positive resist, the part exposed will be soluble in the developer, and the unexposed part will be insoluble. If the photoresist used is a negative resist, the unexposed part will be soluble and the exposed part will be insoluble. The resist used to manufacture the cells can be positive or negative, irrespectively. Next, the insulating layer 103 is deposited (FIG. 5C), and then the layer 104 made of a conductive material 104 is deposited (FIG. 5D). Next, the resist is dissolved (FIG. 5E) in order to obtain layers 103 and 104 made of insulating and conductive materials identically structured with circular apertures exposing the surface of the upper layer of the junction (commonly known as “lift-off”). Next, the layer 106 made of a transparent conductive material (for example ZnO:Al) is deposited (FIG. 5F). In order to allow two of the islands formed in this way to be connected in series (as illustrated in FIG. 2), the layer 101 made of a conductive material may be partially exposed.

FIGS. 5A to 5F show an embodiment of what is called a “bottom to top” process suitable for a CIGS-type junction, a “bottom to top” process being a process in which the layers are deposited in succession on the substrate, from the lowest layer to the highest layer relative to the side exposed to incident light. In the case of CdTe-1 or amorphous-silicon-type junctions (FIGS. 4B, 4C), a “top to bottom” process will be preferred, in which the layers that will be nearer the side exposed to incident light are deposited on the substrate (generally a glass substrate) first, the cell then being flipped when it comes to being used. The choice of whether a top to bottom process is used depends especially on how well the materials employed adhere to the substrate, and on how difficult it might be to make “contact” to the layer made of an absorbent material. Thus, a top to bottom process may comprise: depositing the layer 106 made of a transparent conductive material on a transparent substrate 109 in order to form the front electrical contact; depositing a resist layer structured to form one or more pads, the shape of which will define the shape of the active photovoltaic zone(s); depositing the layer 103 made of an insulating material on said resist layer; lifting off the resist layer; depositing the layer 102 made of an absorbent material; and finally, depositing a conductive layer on the photoconductive layer in order to form the back contact. When the front contact is formed by the layer 106 made of a transparent conductive material and by a structured layer 104 made of a conductive material, it is possible to deposit the layer 104 made of conductive material on the resist layer and then to deposit the insulating layer 103 before the resist has been dissolved. If, as in the embodiment shown in FIG. 4B, it is chosen to insert a layer 106 made of a transparent conductive material between the layer 104 made of a conductive material and the insulating layer 103, it will be possible to deposit the resist pads, deposit the conductive material, dissolve the resist, deposit the layer 106 made of a conductive transparent material, once more deposit resist, deposit the insulating layer and then dissolve the resist.

Moreover, to produce photovoltaic cells of the type shown in FIG. 1B, several production methods may be considered.

According to a first embodiment, the layer 101 made of a conductive material is deposited on a substrate (not shown in FIG. 1B) in order to form the back electrical contact, then the inactive layer 108, advantageously made of an insulating material, is deposited, this layer being structured to form one or more apertures. The absorbent material is then selectively deposited in the one or more apertures so as to foam the layer 102 made of an absorbent material, this layer being discontinuous. The selective deposition is carried out using a suitable method, for example electrodeposition or printing, for example jet printing or screen printing. Next, the layer 106 made of a transparent conductive material is deposited in order to form the front electrical contact. This step may be preceded by the deposition of one or more interface layers and/or of a structured layer 103 made of an insulating material, if the inactive layer 108 is not or not sufficiently insulating, and of the structured layer 104 made of a conductive material forming, with the transparent conductive layer 106, the front electrical contact.

In a second embodiment, the layer 102 made of an absorbent material is deposited on the layer 101 made of a conductive material, said absorbent layer being discontinuous so as to form one or more apertures, an inactive material, for example an insulating material, then being selectively deposited in the one or more apertures so as to form the inactive layer 108. The layer made of an absorbent material is, in this embodiment, deposited by ink jet printing, for example. As before, the layer 106 made of a transparent conductive material is then deposited to form the front electrical contact, this step optionally being preceded by the deposition of a structured layer 103 made of an insulating material, by the deposition of one or more interface layers, and by the deposition of the structured layer 104 made of a conductive material.

According to a variant, the selective deposition of the absorbent material is achieved by depositing grains of the material, obtained using known techniques, for example high-temperature metallurgical synthesis methods, or by generating powders from preliminary vapor-phase deposition on intermediate substrates. CIGS grains of one to several microns in size may thus be prepared and deposited directly on the substrate in the context of the invention. Alternatively, all or some of the layers intended to form the photovoltaic junction may be stacked beforehand, in the form of solid panels, using conventional techniques (for example coevaporation or vacuum sputtering), then portions of the multilayer stack, of dimensions suited to the size of the microcells it is desired to produce, are selectively deposited on the substrate.

According to another variant, the selective deposition of the absorbent material is achieved using a physical or chemical vapor deposition method. To do this, masks will possibly be used, which masks will be placed directly in front of the substrate, and in which apertures are made in order to allow the selective deposition of the absorbent layer and, optionally, other active layers forming the junction on the substrate. Coevaporation and sputtering methods are examples of methods that may be used in this context.

Any one of these embodiments makes it possible, by virtue of the discontinuous nature of the layer of absorbent material obtained, to limit the amount of absorbent material required to produce the photovoltaic cell, and therefore to make a substantial saving in the amount of rare chemical elements used.

Cells according to the invention may thus be produced using processes that involve merely depositing and structuring an electrically neutral layer and an electrically conductive layer. These two layers may very easily be composed of inexpensive and environmentally harmless materials (SiO₂ as the insulator and aluminum as the conductor, for example). The deposition techniques used (sputtering) are very commonplace and not particularly hazardous. The techniques employed are techniques used in the microelectronics industry (UV lithography) for example, the risks of which are limited in terms of toxicity and which may therefore be easily implemented. Scaling up to industrial-scale production may therefore be envisioned on the base of the know-how of the microelectronics industry.

Simulations carried out by the Applicant of the theoretical efficiency of the photovoltaic cells described above returned remarkable results. The model used is based on electrical analysis of a solar cell having a resistive front layer (window layer) with a given sheet resistance. The underlying equations of this model are, for example, described in N. C. Wyeth et al. Solid-State Electronics 20, 629-634 (1977) or U. Malm et al., Progress in Photovoltaics, 16, 113-121 (2008). The Applicant studied the combined effect of light concentration and microcell size in an architecture such as that described above, for a microcell with a circular section, using an electrical contact method not employing a collecting grid.

The model is based entirely on the solution to the equation:

∂²ψ/∂r²+1/r×∂ψ/∂r+R_{□}(Jₚₕ−J₀(exp(qψ/nkT)−1)−ψ/Rₛₕ)=0

where ψ is the electrical potential at a certain distance r from the center of the cell, R_{□} is the sheet resistance of the front window layer, Jₚₕ is the photocurrent density, J₀ is the dark current density, Rₛₕ is the leakage resistance, n is the ideality factor of the diode, k is Boltzmann's constant, and q is the charge on an electron.

The boundary conditions allowing this equation to be solved are, in the case of a peripheral contact:

ψ(a)=V where a is the radius of the cell and V the voltage applied to the latter; and

∂ψ/∂r(0)=0 because no there is no current flow at the center of the cell for reasons of symmetry.

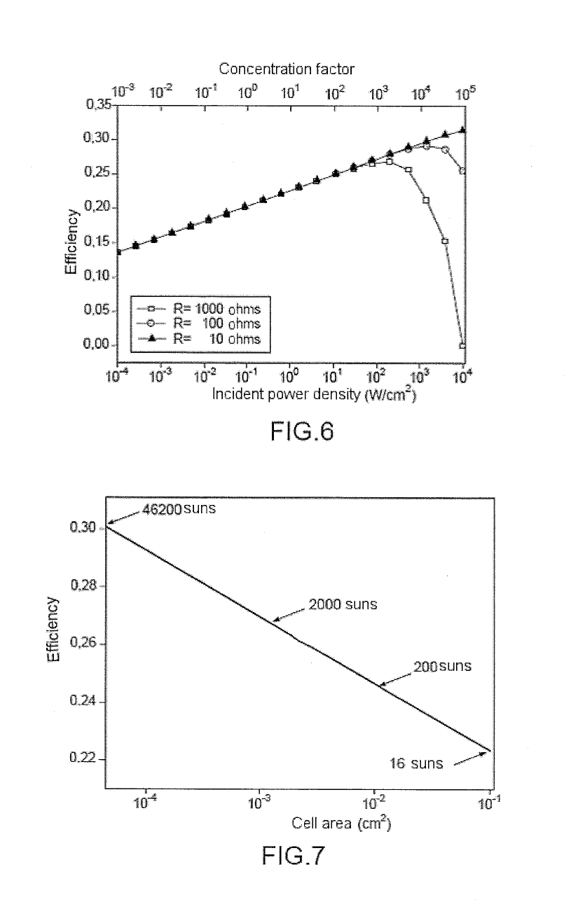

FIG. 6 shows the efficiency curve calculated as a function of the incident power density (or concentration factor in units of suns) for various sheet resistances of the window layer ensuring the peripheral contact of the microcell. To carry out this simulation, a microcell of circular section was considered with a radius of 18 μm (i.e. an area of 10⁻⁵ cm²) and the electrical parameters of a CIGS-based reference cell (without light concentration) were employed, namely a short-circuit current Jsc=35.5 mA/cm², a diode ideality factor of n=1.14, and a dark current J₀=2.1×10⁻⁹ mA/cm² (parameters evaluated, for example, by I.Repins et al., 33rd IEEE Photovoltaic Specialists Conference, 2008, 1-6 (2008), or I.Repins et al., Progress in Photovoltaics 16, 235-239 (2008)).

The efficiency was calculated for three values of the sheet resistance Rₛₕ, 10, 100 and 1000 Ω/Sq, respectively, for luminous power varying between 10⁻⁴ and 10⁴ W/cm², i.e. a concentration factor in units of suns varying between 10⁻³ and 10⁵ (one sun corresponding to 1000 W/m², i.e. 10⁻¹ W/cm²). Thus, for a sheet resistance of 1000 Ω/Sq, the efficiency increases with concentration factor up to about 5000 suns, above which value sheet resistance effects reduce the efficiency. For sheet resistances lower than 100 Ω/Sq, the resistance is no longer the main limiting factor in the calculation of the theoretical efficiency of the cell and efficiencies of about 30% are achieved with concentration factors approaching 50,000 suns.

This is noteworthy in that it is then possible to work with window layers having a better transparency (even if the resistance is higher) allowing larger photocurrents to be generated. Specifically, in the particular case of thin-layer cells for example, the use of a frontside transparent conductive oxide necessarily leads to a compromise between transparency and conductivity. Specifically, the higher the conductivity of the window layer, the less it is transparent. The geometry of the cell according to the inveniton, which relaxes the constraint on the conductivity of the window layer (because resistance effects are rendered negligible), allows very transparent layers to be used (even though the latter are more resistive). An increase in the photocurrent (i.e. the current generated by light incident on the cell) of about 10% is expected since the window layer will absorb less of the incident light, and thus the absorbent part of the cell will receive more light.

FIG. 7 illustrates, under the same calculation conditions as before, the efficiency of the microcell as a function of the area of the active photovoltaic zone for a layer resistance of 10 ohms, the efficiency being given for the value of the optimal concentration factor above which the efficiency decreases. These values of the optimal concentration factor are given for 4 microcell sizes. Thus, for a cell with a section of 10⁻¹ cm², under a concentration of 16 suns, the efficiency calculated was 22%. For a cell with a section of 10⁻² cm², under a concentration of 200 suns, the efficiency calculated was 24%. For a cell with a section of 10⁻³ cm², under a concentration of 2000 suns, the efficiency was 27%, and for a cell with a section of 10⁻⁵ cm², under a concentration of 46,200 suns, the efficiency calculated was 31%. For microcells with sections smaller than 4.5×10⁻⁵ cm², the optimal concentration factor was higher than 46,200, showing that sheet resistance was no longer a factor limiting the performance of the microcell.

As will be clear from the results presented, the novel architecture of the photovoltaic cell according to the invention especially allows the influence of the resistance of the window layer to be limited, and thus allows much higher concentrations to be used, these concentrations being associated with higher conversion efficiencies. Several advantages are obtained. Using microcells under a concentrated flux especially enables the ratio of the amount of raw material used to the energy produced to be reduced. A material saving of a factor higher than or equal to the light concentration is then possible. The energy produced per gram of raw material used could be multiplied by a factor of one hundred or even several thousand, depending on the light concentration employed. This is particularly important for materials such as indium, the availability of which is limited. Moreover, under light concentration, materials of average quality could be used without a substantial decrease in performance, since it is known that using a concentrated flux saturates electrical defects in the material. Saturation of these defects thus makes it possible to neutralize their influence on the performance of the cell. Very high efficiencies could therefore be obtained using materials which, without concentration, would remain substandard. This means, for example, that materials having a limited cost could be suitable for use under concentration.

The invention moreover uses the already tried-and-tested techniques of microelectronics to define the microcells, and it is therefore suitable for many existing photovoltaic technologies, even though, at the present time, the most promising applications are expected to be in the field of thin-layer cells.

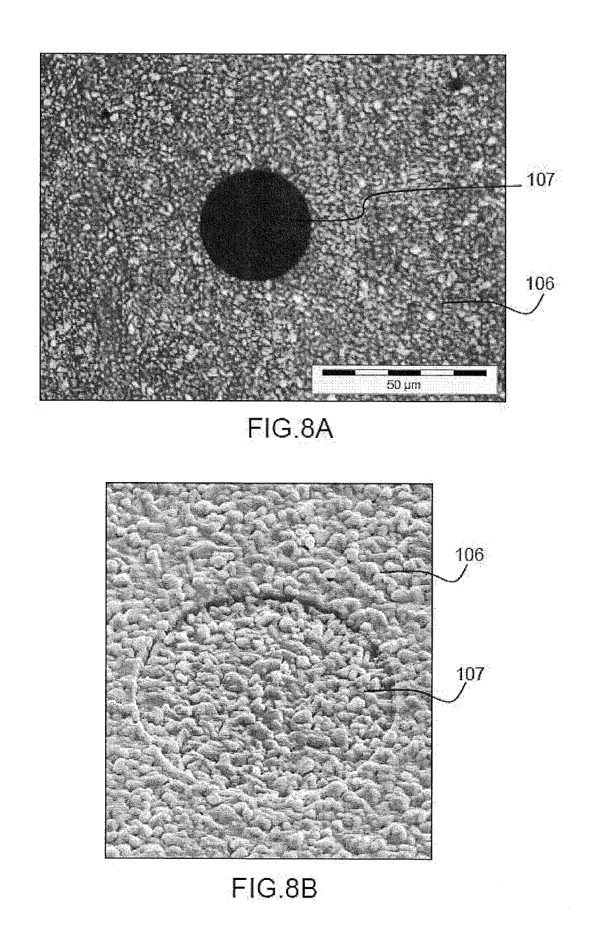

The Applicants have produced prototype microcells using one embodiment of a process described in the present invention. FIGS. 8A and 8B show micrographs of a CIGS-based microcell as seen from above, respectively taken with an optical microscope (FIG. 8A) and with a scanning electron microscope (SEM) (FIG. 8B). The microcells were produced using the process described with reference to FIGS. 5A to 5F, with round sections having diameters varying between 10 μm and 500 μm. The microcells shown in FIGS. 8A and 8B are microcells with a diameter of 35 μm. In these micrographs, the reference 106 indicates the window layer made of ZnO:Al deposited on the layer 104, and the reference 107 indicates the exposed area corresponding to the active photovoltaic zone. With these cells, the Applicants recorded very promising initial results, exhibiting the beneficial effect of the size of the microcell on the performance under concentration, without degradation of the materials even under the highest densities tested (100 time more than previously described in the literature; see, for example, the paper by J. Ward et al. cited above). In particular, current densities equivalent to a concentration of 3000 suns were obtained in the microcell (current density higher than 100 A/cm²).

Although described by way of a certain number of detailed embodiments, the photovoltaic cell and the method for producing the cell according to the invention include various modifications, improvements and variants that will be obvious to those skilled in the art, it being understood, of course, that these various modifications, improvements and variants form part of the scope of the invention as defined by the following claims.

1. A photovoltaic component comprising:
a set of layers suitable for producing a photovoltaic device, comprising at least one first layer made of a conductive material forming a back electrical contact, a second layer made of a material that is absorbent in the solar spectrum, and a third layer made of a transparent conductive material forming a front electrical contact;
an electrically insulating layer, arranged between said back electrical contact and said front electrical contact, containing a plurality of apertures, each aperture defining a zone in which said layers of said set of layers are stacked to form a photovoltaic microcell; and
a fourth layer made of a conductive material, making electrical contact with said third layer made of a transparent conductive material, forming the front electrical contact with said third layer, and structured in such a way as to form a peripheral electrical contact for each of said photovoltaic microcells formed, said photovoltaic microcells being electrically connected in parallel by the back electrical contact and the front electrical contact.

2. The photovoltaic component as claimed in claim 1, in which said conductive material of said fourth layer is a metal selected from the group consisting of aluminum, molybdenum, copper, nickel, gold, silver, carbon and carbon derivatives, platinum, tantalum and titanium.

3. The photovoltaic component as claimed in claim 1, wherein said first layer made of a conductive material forming the back contact is transparent and wherein the fourth layer further comprises a layer made of a conductive material making electrical contact with said first layer and structured in such a way as to form a peripheral electrical contact for said photovoltaic microcells.

4. The photovoltaic component as claimed in claim 1, in which the electrically insulating layer comprises a layer made of an insulating material structured to form said apertures.

5. The photovoltaic component as claimed in claim 4, further comprising a second layer made of an insulating material, said layer being arranged between said back electrical contact and said front electrical contact, and being structured to form apertures of equal or smaller size centered on said apertures in the first layer made of insulating material.

6. The photovoltaic component as claimed in claim 4, in which said insulating material is selected from the group consisting of oxides such as silica or alumina, nitrides such as silicon nitride, and sulfides such as zinc sulfide.

7. The photovoltaic component as claimed in claim 1, in which the electrically insulating layer comprises an insulating gas.

8. The photovoltaic component as claimed in claim 1, in which at least one dimension of a section of each of said photovoltaic microcells is smaller than 1 mm and preferably smaller than 100 μm.

9. The photovoltaic component as claimed in claim 1, in which at least some of the photovoltaic microcells formed have a circular section with an area smaller than 10⁻² cm².

10. The photovoltaic component as claimed in claim 1, in which at least one of the photovoltaic microcells formed has a strip-shaped elongate section, a smaller dimension of which is smaller than 1 mm.

11. The photovoltaic component as claimed in claim 1, in which said second layer made of an absorbent material is discontinuous and formed in a location of said photovoltaic microcells.

12. The photovoltaic component as claimed in claim 11, further comprising a layer that is inactive with respect to the photovoltaic device, the layer comprising apertures in the locations in which said absorbent material is selectively placed.

13. The photovoltaic component as claimed in claim 1, wherein each of said layers forming the photovoltaic component has a thickness of less than about 20 μm.

14. The photovoltaic component as claimed in claim 13, wherein the absorbent material belongs to a family selected from the group consisting of:
the CIGS family, the CdTe family, the silicon family, and the III-V semiconductor family.

15. An array of photovoltaic components, each of the photovoltaic components in the array being a photovoltaic component as claimed in claim 1, wherein said photovoltaic components are electrically connected in series, the front contact of one photovoltaic component being electrically connected to the back contact of an adjacent photovoltaic component.

16. A photovoltaic module comprising:
a photovoltaic component as claimed in claim 1; and
a system for concentrating solar light, the system being suitable for focusing all or some of the incident light on each of said photovoltaic microcells of the one or more photovoltaic components.

17. The photovoltaic module as claimed in claim 15, the first layer being made of a conductive material of the back contact being transparent, it further comprises:
a layer made of a conductive material making electrical contact with said first layer made of a transparent conductive material so as to form the back electrical contact with said first layer, and structured in such a way as to form a peripheral electrical contact for said photovoltaic microcells, and
an element for converting the wavelength of the incident light to a spectral band absorbed by the absorbent material arranged under said first layer made of a transparent conductive material of the back contact.

18. A method for manufacturing a photovoltaic component as claimed in claim 1, further comprising:
depositing said first layer made of a conductive material on a substrate to form the back electrical contact;
depositing a layer made of an electrical insulator that is inactive with respect to the photovoltaic device, said inactive layer being structured to form a plurality of apertures;
selectively depositing the absorbent material in said apertures so as to form said second layer made of an absorbent material, said second layer being discontinuous;
depositing said fourth layer made of a conductive material, said fourth layer being structured in such a way as to form apertures of smaller or equal sizes to those of the apertures in said inactive layer; and
depositing said third layer made of a transparent conductive material so as to form the front electrical contact of the photovoltaic microcells, this third layer making electrical contact with said fourth layer made of a conductive material.

19. A method for manufacturing a photovoltaic component as claimed in claim 1, further comprising:
depositing said first layer made of a conductive material on a substrate so as to form the back electrical contact;
depositing said second layer made of an absorbent material, said second layer being discontinuous and containing a plurality of apertures;
selectively depositing in said apertures an electrical insulator that is inactive with respect to the photovoltaic device form a discontinuous inactive layer having apertures in the location of the absorbent material;
depositing said fourth layer made of a conductive material, the fourth layer being structured as to form apertures of smaller or equal sizes to those of the apertures in said inactive layer; and
depositing said third layer made of a transparent conductive material, the third layer making electrical contact with said fourth layer made of a conductive material, to form the front electrical contact.

20. The manufacturing method as claimed in claims 19, wherein the deposition of the second layer made of an absorbent material comprises depositing portions of a multilayer stack produced beforehand, said multilayer stack comprising layers of said set of layers suitable for producing a photovoltaic device.

21. The manufacturing method as claimed in claim 19, further comprising deposition of the electrically insulating layer structured to form apertures of smaller or equal sizes to those in said inactive layer.

22. A method for manufacturing a photovoltaic component as claimed in claim 1, further comprising:
depositing, on a substrate, said first layer made of a conductive material so as to form the back electrical contact, and said second layer made of an absorbent material;
depositing a layer of resist structured to form a plurality of pads the shape of which will define the shape of each of said photovoltaic microcells;
depositing on said resist layer the electrically insulating layer and the fourth layer made of a conductive material; and
lifting off the resist layer in order to obtain said electrically insulating layer and said fourth layer made of a conductive material, and depositing said third layer made of a transparent conductive material, this layer making electrical contact with said structured layer made of a conductive material, so as to form the front electrical contact.

23. A method for manufacturing a photovoltaic component as claimed in claim 1, comprising:
depositing said third layer made of a transparent conductive material on a transparent substrate to form the front electrical contact;
depositing a layer of resist structured to form a plurality of pads the shape of which will define the shape of each of said photovoltaic microcells;
depositing on said resist layer the fourth layer made of a conductive material and the electrically insulating layer;
lifting off the resist layer in order to obtain said electrically insulating layer made of an insulating material and said fourthstructured layer made of a conductive material, and depositing said second layer made of an absorbent material; and
depositing said first layer made of a conductive material so as to form the back electrical contact.

24. The method for manufacturing a photovoltaic component as claimed in claim 22, wherein said second layer made of an absorbent material is deposited selectively and forms a discontinuous layer.
